(19) United States
(12) Patent Application Publication
(10) Pub. No.: US 2024/0194769 A1
(43) Pub. Date: Jun. 13, 2024

(54) SEMICONDUCTOR DEVICE AND METHOD FOR FORMING THE SAME

(71) Applicant: Fujian Jinhua Integrated Circuit Co., Ltd., Quanzhou City (CN)

(72) Inventors: Chia-Wei Wu, Quanzhou City (CN); Yu-Cheng Tung, Quanzhou City (CN)

(73) Assignee: Fujian Jinhua Integrated Circuit Co., Ltd., Quanzhou City (CN)

(21) Appl. No.: 18/124,563

(22) Filed: Mar. 21, 2023

(30) Foreign Application Priority Data
Dec. 9, 2022 (CN) 202211583306.5
Dec. 9, 2022 (CN) 202223309144.4

(51) Int. Cl. H01L 29/66; C23C 16/40; C23C 16/455; H01L 21/02; H01L 29/24; H01L 29/786

(52) U.S. Cl. CPC H01L 29/66969; C23C 16/407; C23C 16/45529; C23C 16/45553; H01L 21/02554; H01L 21/02565; H01L 21/0262; H01L 29/24; H01L 29/78648; H01L 29/7869; H01L 29/78693; H01L 29/78696

(57) ABSTRACT

A method for forming a metal oxide semiconductor device includes performing a first atomic layer deposition cycle M times to form a first stacked channel layer and a second atomic layer deposition cycle N times to form a second stacked channel layer on the first stacked channel layer. M and N are positive integers. The first stacked channel layer and the second stacked channel layer have different metal compositions and collectively form the channel layer of the metal oxide semiconductor device.

### BACKGROUND OF THE INVENTION

### 1. Field of the Invention

The present invention relates to a semiconductor device and method for forming the same. More particularly, the present invention relates to a semiconductor device including oxide semiconductor channel layer and method for forming the same.

### 2. Description of the Prior Art

A thin-film transistor (TFT) is a field-effect transistor with a semiconductor layer deposited on a substrate as the active layer (channel layer), and may be easily fabricated on various substrates, such as wafers, glass substrates, ceramic substrates, or plastic substrates made of high molecular polymers such as polyimide (PI), polycarbonate (PC) or polyethylene terephthalate (PET). The manufacturing process of a thin-film transistor may be easily integrated with the back end of line (BEOL) process of integrated circuits, allowing a higher flexibility for circuit design to improve area efficiency and device performance. For example, it has been drawn attention in the field to utilize thin film transistors to form embedded memories in circuitry. Oxide semiconductors are particularly suitable materials as the active layers (channel layers) of thin film transistors due to their advantages characteristics such as high field effect mobility, low deposition temperature, and good film uniformity.

### SUMMARY OF THE INVENTION

One object of the present invention is to provide a semiconductor device including an oxide semiconductor channel layer and a method for forming the same. The oxide semiconductor channel layer of the semiconductor device is formed by a two-stage atomic layer deposition process, such that along the thickness direction, the oxide semiconductor channel layer may be divided into two distinguishable portions that have different composition concentrations respectively designed for threshold voltage carrier mobility. In this way, a stable threshold voltage and increased carrier mobility may be achieved at the same time.

One embodiment of the present invention provides a method for forming a semiconductor device including the following steps. A substrate is provided. A first atomic layer deposition cycle is performed M times to form a first stacked channel layer on the substrate. A second atomic layer deposition cycle is performed N times to form a second stacked channel layer on the first stacked channel layer, wherein M and N are positive integers, and a concentration of a metal composition of the second stacked channel layer is greater than a concentration of the metal composition of the first stacked channel layer. A gate dielectric layer is formed on the second stacked channel layer. A gate structure is formed on the gate dielectric layer.

Another embodiment of the present invention provides a method for forming a semiconductor device including the following steps. A substrate is provided. A bottom electrode is formed on the substrate. A bottom gate dielectric layer is formed on the bottom electrode. A first atomic layer deposition cycle is performed N times to form a first stacked channel layer on the bottom gate dielectric layer. A second atomic layer deposition cycle is performed M times to form a second stacked channel layer on the first stacked channel layer, wherein M and N are positive integers, and a concentration of a metal composition of the first stacked channel layer is greater than a concentration of the metal composition of the second stacked channel layer.

Still another embodiment of the present invention provides a semiconductor device including a first stacked channel layer comprising a first surface and a second surface, a first gate structure disposed on the first surface of the first stacked channel layer, a first gate dielectric layer disposed between the first gate structure and the first stacked channel layer, and a second stacked channel layer disposed between the first gate dielectric layer and the first stacked channel layer, wherein a concentration of a metal composition of the second stacked channel layer is greater than a concentration of the metal composition of the first stacked channel layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. Relative dimensions and proportions of parts of the drawings have been shown exaggerated or reduced in size, for the sake of clarity and convenience in the drawings. The same reference signs are generally used to refer to corresponding or similar features in modified and different embodiments.

FIG. 1 is a schematic drawing illustrating a cross-sectional view of a semiconductor device according to a first embodiment of the present invention.

FIG. 2 is a schematic drawing illustrating the steps of a first atomic layer deposition cycle according to an embodiment of the present invention.

FIG. 3 is a schematic drawing illustrating the steps of a second atomic layer deposition cycle according to an embodiment of the present invention.

FIG. 4 is a schematic drawing illustrating a cross-sectional view of a semiconductor device according to a second embodiment of the present invention.

FIG. 5 is a schematic drawing illustrating a cross-sectional view of a semiconductor device according to a third embodiment of the present invention.

FIG. 6 is a schematic drawing illustrating a cross-sectional view of a semiconductor device according to a fourth embodiment of the present invention.

FIG. 7 is a schematic drawing illustrating a cross-sectional view of a semiconductor device according to a fifth embodiment of the present invention.

### DETAILED DESCRIPTION

To provide a better understanding of the present invention to those of ordinary skill in the art, several exemplary embodiments of the present invention will be detailed as follows, with reference to the accompanying drawings using numbered components to elaborate the contents and effects to be achieved. Other embodiments may be utilized and that structural, logical and electrical changes may be made without departing from the spirit and scope of the present invention.

The drawings only depict a portion of the semiconductor device for the sake of clarity and simplicity. Specific components in the drawings are not drawn according to their actual relative dimensions and proportions. In addition, the number and size of each component in the drawings are only for illustration, and are not intended to limit the scope of the present invention. The spatial relationships described in the following specification refer to relative positions of the components. The semiconductor device may be presented in different orientations without changing the relative spatial relationships of the components thereof, which are all included in the scope of the present invention.

It will be understood that when a component or layer is referred to as being “on” or “connected to” another component or layer, it may be directly on or directly connected to the other component or layer, or may have intervening components or layers disposed therebetween. On the contrary, when a component is referred to as being “directly on” or “directly connected to” another component or layer, there are no intervening components or layers disposed therebetween.

The term “substrate” used herein refers to a structure having an exposed surface on which material layers for forming components of a semiconductor device may be disposed. The substrate used in the present invention may be a semiconductor wafer or a substrate made of other suitable materials. In some embodiments of the present invention, the term “substrate” used herein may include the substrate itself and the layers that have been fabricated on the substrate.

The terms “form”, “deposit” or “dispose” are used herein to describe the act of applying a material layer to the substrate. If the process is not specified in the specification, it may be implemented by any suitable process such as physical vapor deposition (PVD), chemical vapor deposition (CVD), electrochemical deposition (ECD), molecular beam epitaxy (MBE), atomic layer deposition (ALD), high density plasma chemical vapor deposition (HDP-CVD), plasma-enhanced chemical vapor deposition (PECVD), sputtering, evaporation, electroplating, or any other suitable processes.

The naming convention “first”, “second”, “third”, etc., may be used in claims and in the specification to describe components in order to distinguish different components from each other and do not necessarily indicate a physical positioning or operational ordering of the components unless the specification indicates otherwise. A particular component may be described by different names in the claims and in the specification, and/or the claims and specification may have different naming conventions depending on context of the discussion or the order in which the components are declared in the claims.

The present invention may be applied to any device including an oxide semiconductor channel layer, such as transistors, diodes, resistors, capacitors, and memories, but are not limited thereto.

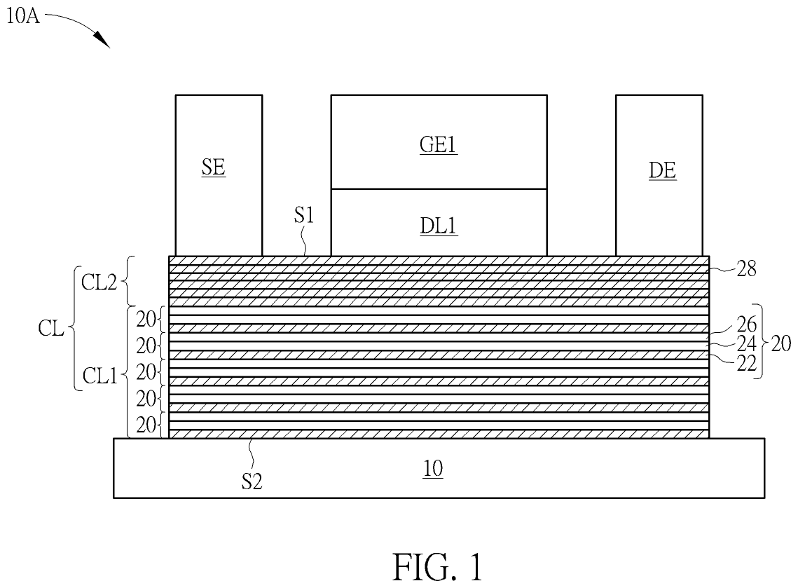

Please refer to FIG. 1, which is a schematic drawing illustrating a cross-sectional view of a semiconductor device 10A according to a first embodiment of the present invention. As shown in FIG. 1, the semiconductor device 10A includes a substrate 10, a channel layer CL, a gate dielectric layer DL1, a gate structure GE1, a source structure SE and a drain structure DE.

The substrate 10 may include a semiconductor substrate, such as a silicon substrate, an epitaxial silicon substrate, a silicon germanium (SiGe) substrate, a silicon carbide (SiC) substrate, or a silicon-on-insulator (SOI) substrate, but is not limited thereto. In some embodiments of the present invention, the substrate 10 may include circuit components and/or interconnection structures (not shown) fabricated formed thereon through semiconductor manufacturing processes, wherein the circuit components may include active or passive components such as transistors, diodes, resistors, and capacitors, but are not limited to. The interconnection structures may include interlayer dielectric layers and conductive structures formed in the interlayer dielectric layers such as metal interconnections, contact plugs, and conductive pads. In some embodiments of the present invention, the substrate 10 may include a non-semiconductor substrate, such as a substrate made of glass, ceramics, quartz, sapphire, polyimide (PI), polycarbonate (PC), polyethylene terephthalate (PET), silicon oxide coating layers, silicon nitride coating layers, or a combination of the above non-semiconductor materials, but is not limited thereto.

The channel layer CL is a stacked layer composed of a plurality of nanometer films. The channel layer CL includes a first surface S1 and a second surface S2 that are opposite to each other. The channel layer CL is disposed in a way that the second surface S2 faces the substrate 10. It is noticeable that according to the materials and stacking sequences of the component layers, the channel layer CL may be divided into a first stacked channel layer CL1 and a second stacked channel layer CL2 along the thickness direction. As shown in FIG. 1, the first stacked channel layer CL1 may be essentially composed of a plurality of composite sub-layers 20, wherein each of the composite sub-layer 20 is essentially composed of a first metal oxide layer 22, a second metal oxide layer 24 and a third metal oxide layer 26 that are stacked one on another sequentially. The second stacked channel layer CL2 is essentially composed of a plurality of fourth metal oxide layers 28. It should be noted that the number of the composite sub-layers 20 of the first stacked channel layer CL1, the number of the fourth metal oxide layers 28 of the second stacked channel layer CL2, and the numbers and stacking sequence of the first metal oxide layers 22, the second metal oxide layers 24, the third metal oxide layers 26 of each of the composite sub-layer 20 shown in FIG. 1 are only examples and may be adjusted according to device design requirements.

The first metal oxide layer 22, the second metal oxide layer 24, the third metal oxide layer 26, and the fourth metal oxide layer 28 are respectively made of a metal oxide material including a metal composition preferably selected from a group comprising indium (In), gallium (Ga), zinc (Zn), indium gallium (InGa), indium zinc (InZn), gallium zinc (GaZn), and indium gallium zinc (InGaZn). According to an embodiment of the present invention, the first metal oxide layer 22 is essentially made of indium oxide (InO), the second metal oxide layer 24 is essentially made of gallium oxide (GaO), the third metal oxide layer 26 is essentially made of zinc oxide (ZnO), and the fourth metal oxide layer 28 is essentially made of indium oxide (InO). The indium (In) composition is the main electron pathway former in the channel layer CL. The gallium (Ga) composition is mainly employed to control the carrier density of the channel layer CL. The zinc (Zn) is mainly employed to adjust the overall crystalline/amorphous degree of the channel layer CL. The first stacked channel layer CL1 may be also referred to as an indium gallium zinc oxide (IGZO) layer, and the second stacked channel layer CL2 may be alternatively referred to as an indium oxide (InO) layer.

The gate dielectric layer DL1 is dispose on the first surface S1 of the channel layer CL. gate dielectric layer DL1 may be a single layer structure, or may be composed of multiple dielectric layers. The material suitable for forming the gate dielectric layer DL1 may include silicon oxide (SiO₂), silicon nitride (SiN), silicon oxynitride (SiON), silicon carbide nitride (SiCN), high-k dielectric materials such as hafnium oxide (HfO₂), hafnium silicon oxide (HfSiO₄), hafnium silicon oxynitride (HfSiON), aluminum oxide (AIO), zinc oxide (ZrO₂), titanium oxide (TiO₂), other metal oxide dielectrics, or a combination thereof, but is not limited thereto. According to an embodiment of the present invention, the gate dielectric layer DL1 includes silicon oxide.

The gate structure GE1 is disposed on the gate dielectric layer DL1, and is spaced apart from the channel layer CL by the gate dielectric layer DL1. The source structure SE and the drain structure DE are disposed on the first surface S1 of the channel layer CL, directly contacting the second stacked channel layer CL2 of the channel layer CL, and are respectively at two sides of the gate structure GE1. The gate structure GE1, the source structure SE and the drain structure DE are respectively made of a conductive material, such as aluminum (Al), titanium (Ti), tantalum (Ta), tungsten (W), niobium (Nb), molybdenum (Mo), copper (Cu), titanium nitride (TiN), titanium carbide (TiC), tantalum nitride (TaN), titanium tungsten (Ti/W), titanium and titanium nitride (Ti/TiN), polysilicon, doped silicon, silicide, other suitable metal or non-metal conductive materials, or a combination thereof, but is not limited thereto. In some embodiments of the present invention, the portions of the channel layer CL that are in direct contact with the source structure SE and the drain structure DE may include n-type or p-type dopants to reduce the interface resistance between the channel layer CL and the source structure SE and the drain structure DE.

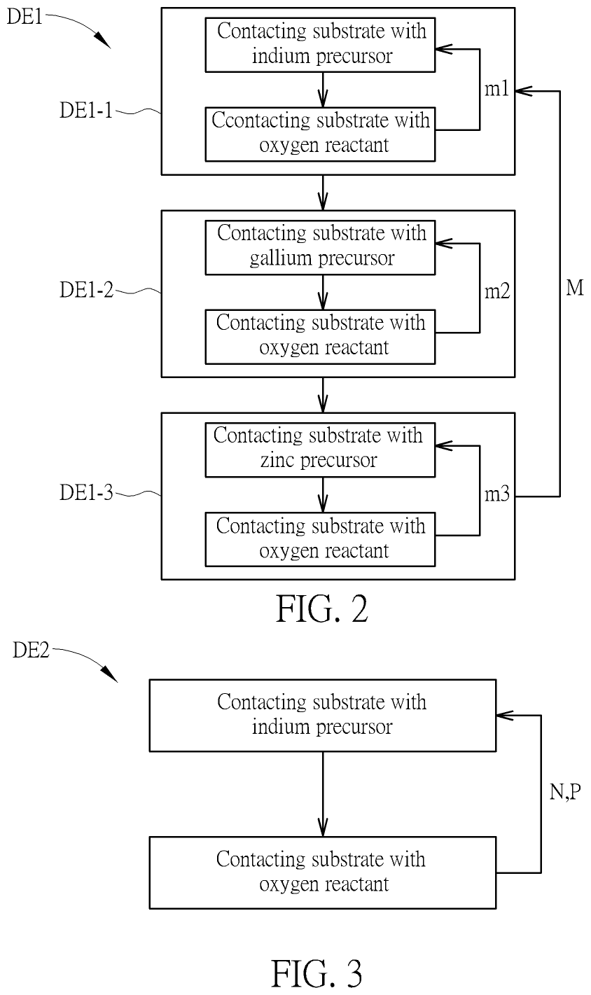

According to some embodiments of the present invention, the semiconductor device 10A may be formed by the following manufacturing steps. First, the substrate 10 is provided. Next, a first atomic layer deposition cycle (such as the first atomic layer deposition cycle DE1 shown in FIG. 2) is performed M times (M is a positive integer equal to or larger than 1) to form the first stacked channel layer CL1 on the substrate 10. Following, a second atomic layer deposition cycle (such as the first atomic layer deposition cycle DE2 shown in FIG. 3) is performed N times (N is a positive integer equal to or larger than 1) to form the second stacked channel layer CL2 immediately on the first stacked channel layer CL1. The first stacked channel layer CL1 and the second stacked channel layer CL2 collectively form the channel layer CL. Subsequently, deposition processes are performed to form the gate dielectric layer DL1 and a gate material layer (such as a conductive layer, not shown) on the second stacked channel layer CL2. A series of patterning processes (such as lithography and etching process) may be performed to remove unnecessary portions of the gate dielectric layer DL1, the gate material layer (not shown), and the channel layer CL, thereby obtaining the patterned gate dielectric layer DL1, the gate structure GE1, and the channel layer CL as shown in FIG. 1. In some embodiments of the present invention, the channel layer CL may be patterned before forming the gate dielectric layer DL1 and the gate material layer on the substrate 10. In some embodiments of the present invention, an optional ion implantation process using the gate structure GE1 as a mask may be performed to implant n-type (such as arsenic) or p-type (such as boron) dopant into the exposed portions of the channel layer CL at two sides of the gate structure GE1 to adjust the conductivity. After that, a deposition process is performed to form a conductive layer (not shown) on the channel layer CL and, and a patterning process is performed to pattern the conductive layer into the source structure SE and the drain structure DE. In some embodiments of the present invention, an optional annealing process or plasma treatment may be performed at any suitable time after the channel layer CL is formed to adjust the electrical properties of the channel layer CL.

Please refer to FIG. 2, which is a schematic drawing illustrating the steps of the first atomic layer deposition cycle DE1 according to an embodiment of the present invention. A completion of the first atomic layer deposition cycle DE1 forms a composite sub-layer 20 of the first stacked channel layer CL1. The first atomic layer deposition cycle DE1 may be a plasma-enhanced atomic layer deposition (PEALD) super cycle that is consist of a plurality of sub-cycles. Each sub-cycle includes supplying a metal precursor (as a gas pulse) to the deposition chamber to contact and be absorbed on the surface of the substrate 10 and, then supplying an oxygen reactant (as a gas pulse) to the deposition chamber to react with the absorbed metal precursor to form a metal oxide layer. In some embodiments of the present invention, each sub-cycle may further include vacuum pumping the deposition chamber after each gas pulse to evacuate the deposition chamber or purging the deposition chamber with an inert gas such as argon (Ar) or nitrogen (N2) to remove excess metal precursors, oxygen reactants, and reaction by-products from the deposition chamber.

Please still refer to FIG. 2. In some embodiments of the present invention, each first atomic layer deposition cycle DE1 includes successively performing a sub-cycle DE1-1 m1 times to form the first metal oxide layer 22, performing a sub-cycle DE1-2 m2 times to form the second metal oxide layer 24, and then performing a sub-cycle DE1-3 m3 times to form the third metal oxide layer 26, wherein m1, m2 and m3 are positive integer equal to or larger than 1. It should be noted that the sequence of the sub-cycles DE1-1, DE1-2 and DE1-3 shown in FIG. 2 is an example and should not be construed to exclusively limit the scope of the present invention. The sequence of the sub-cycles DE1-1, DE1-2 and DE1-3 may be adjusted according to the expected stacking sequence of the first metal oxide layer 22, the second metal oxide layer 24, and the third metal oxide layer 26 of the composite sub-layer 20.

In some embodiments of the present invention, each sub-cycle DE 1-1 includes contacting the substrate 10 with an indium precursor and then with an oxygen reactant to form the first metal oxide layer 22, each sub-cycle DE 1-2 includes contacting the substrate 10 with a gallium precursor and then with the oxygen reactant to form the second metal oxide layer 24, and each sub-cycle DE 1-3 includes contacting the substrate 10 with a zinc precursor and then with the oxygen reactant to form the third metal oxide layer 26. In some embodiments of the present invention, the indium precursor includes [3-(dimethylamino) propyl] dimethyl indium (DADI), the gallium precursor includes tri-methylgallium (TMGa), the zinc precursor includes diethyl zinc, and the oxygen reactant includes oxygen (O₂), but are not limited thereto. In some embodiments of the present invention, additional gases such as, but not limited to, NH₃, N₂O, NO₂, H₂O₂, may be provided to the deposition chamber with the precursors or reactant to assist the reaction to improve the quality of the metal oxide layers.

Please refer to FIG. 3, which is a schematic drawing illustrating the steps of the second atomic layer deposition cycle DE2 according to an embodiment of the present invention. A completion of the second atomic layer deposition cycle DE2 forms a fourth metal oxide layer 28 of the second stacked channel layer CL2. The second atomic layer deposition cycle DE2 may be a plasma-enhanced atomic layer deposition (PEALD) that is consist of the same steps as the sub-cycle DE 1-1 of the first atomic layer deposition cycle DE1 shown in FIG. 2, and therefore the fourth metal oxide layer 28 obtained by the second atomic layer deposition cycle DE2 and the first metal oxide layer 22 obtained by the sub-cycle DE 1-1 (also the bottom-most layer of the first stacked channel layer CL1) have essentially the same material. For example, each second atomic layer deposition cycle DE2 includes contacting the substrate 10 with an indium precursor and then with an oxygen reactant to form the fourth metal oxide layer 28.

In some embodiments of the present invention, the first atomic layer deposition cycle DE1 and the second atomic layer deposition cycle DE2 are performed in the same deposition chamber consecutively in-situ, without breaking the vacuum seal of the deposition chamber. In some embodiments of the present invention, the gate dielectric layer DL1 may be formed through an atomic layer deposition process performed consecutively after the second atomic layer deposition cycle DE2 in the same deposition chamber.

In some embodiments of the present invention, the first atomic layer deposition cycle DE1 and the second atomic layer deposition cycle DE2 are performed at a processing temperature not higher than 400° C., respectively. such as between 20° C. and 400° C., between 100° C. and 350° C., or between 150° C. and 300° C.

In some embodiments of the present invention, the processing temperature of the second atomic layer deposition cycle DE2 may be higher than the processing temperature of the first atomic layer deposition cycle DE1 to improve the carrier mobility of the second stacked channel layer CL2.

The thicknesses of the first stacked channel layer CL1 and the second stacked channel layer CL2 may be adjusted by controlling the numbers of the component layers, which are determined by the number of times M and N of the first atomic layer deposition cycle DE1 and the second atomic layer deposition cycle DE2.

The thicknesses of the component layers of the first stacked channel layer CL1, that are, the first metal oxide layer 22, the second metal oxide layer 24, the third metal oxide layer 26, may be adjusted by controlling the times m1, m2, and m3 of the cub-cycles DE1-1, DE1-2, and DE1-3. For example, when m1=1, each first metal oxide layer 22 includes a single layer of indium oxide (InO). When m1=2, each first metal oxide layer 22 includes two layers of indium oxide (InO). The same concept also applies to the second metal oxide layer 24 and the third metal oxide layer 26.

In some embodiments of the present invention, in order to form a channel layer CL with an optimized layer structure and composition concentrations for an improved carrier mobility, preferably, N is larger than M or is about 1 to 1.5 times of M, and m1, m2 and m3 are respectively smaller than both M and N. For example, M may be between 5 and 10, N may be between 10 and 15, and m1, m2, and m3 are respectively 1. The produced first stacked channel layer CL1 may be composed of 5 to 10 composite sub-layers 20, wherein each sub-layer 20 is composed of one indium oxide (InO) layer, one gallium oxide (GaO) layer, and one zinc oxide (ZnO) layer. The atomic concentration (or atomic percentage) of indium, gallium, zinc, and oxygen in the first stacked channel layer CL1 are respectively between 16% and 25%, or have a ratio approximately 1:1:1:1. The produced second stacked channel layer CL2 may be composed of 10 to 15 indium oxide (InO) layers, wherein the atomic concentration of indium and oxygen in the second stacked channel layer CL2 are respectively between 45% and 55%, or have a ratio approximately 1:1. Due to different compositions and different atomic concentration of the compositions between the first stacked channel layer CL1 and the second stacked channel layer CL2, the amorphousness degrees thereof may be different, such that the channel layer CL may be referred to as a heterogeneous channel layer. In some cases, the amorphousness degree of the first stacked channel layer CL1 may be higher than the second stacked channel layer CL2. The heterogeneous channel layer CL using the second stacked channel layer CL2 (higher In concentration and crystalline level) closer to the gate structure GE as the major channel region may achieve a stable threshold voltage and an increased carrier mobility at the same time.

The heterogeneous channel layer provided by the prevent invention may be used to form other types of semiconductor devices. The following description will detail the different embodiments of the present invention. To simplify the description, identical components in each of the following embodiments are marked with identical symbols. For making it easier to understand the differences between the embodiments, the following description will detail the dissimilarities among different embodiments and the identical features will not be redundantly described.

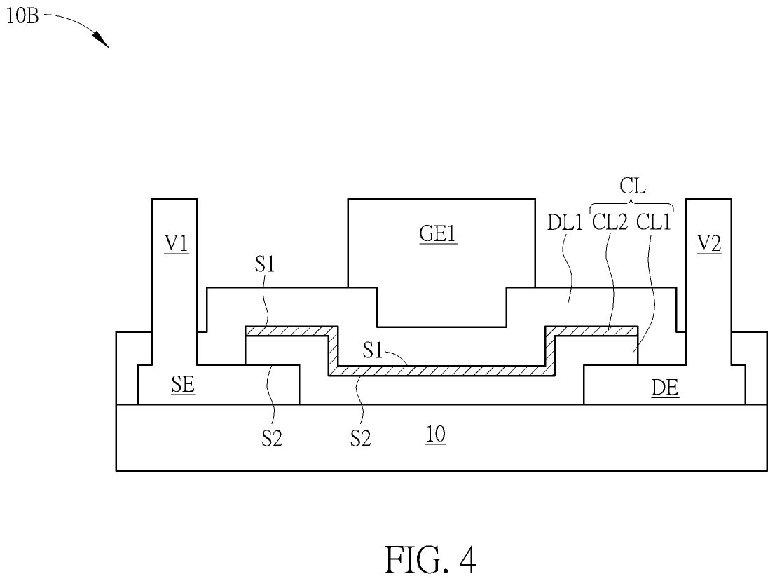

Please refer to FIG. 4, which is a schematic drawing illustrating a cross-sectional view of a semiconductor device 10B according to a second embodiment of the present invention. The semiconductor device 10B includes a substrate 10, a channel layer CL, a gate dielectric layer DL1, a gate structure GE1, and a source structure SE and a drain structure DE. The difference between the semiconductor device 10B shown in FIG. 4 and the semiconductor device 10A shown previously in FIG. 1 is that the source structure SE and the drain structure DE of the semiconductor device 10B are disposed between the substrate 10 and the channel layer CL, on the second surface S2 of the channel layer opposite to the first surface S1 and the gate structure GE1. The semiconductor device 10B may be formed by the following manufacturing steps. First, the substrate 10 is provided. Next, a conductive layer (not shown) is formed on the substrate 10 and be patterned to form the source structure SE and the drain structure DE. Following, the first atomic layer deposition cycle DE1 (shown in FIG. 2) is performed M times to form the first stacked channel layer CL1 on the substrate 10 and the source structure SE and the drain structure DE. After that, the second atomic layer deposition cycle DE2 (shown in FIG. 3) is performed N times to form the second stacked channel layer CL2 on the first stacked channel layer CL1. The first stacked channel layer CL1 and the second stacked channel layer CL2 collectively form the channel layer CL. The materials and composition concentrations of the first stacked channel layer CL1 and the second stacked channel layer CL2 may be referred to the description as set forth in the first embodiment, and will not be repeated herein. After patterning the channel layer CL, a gate dielectric layer DL1 and a gate material layer (not shown) on the channel layer CL are formed, and the gate material layer is then patterned to form the gate structure GE1 as shown in FIG. 4. After that, manufacturing processes such as etching, deposition, and patterning are performed to form a source contact V1 and a drain contact V2 that respectively penetrate through the gate dielectric layer DL1 and electrically connect to the source structure SE and the drain structure DE. In some embodiments of the present invention, the bottom-most layer of the first stacked channel layer CL1 that is in direct contact with the source structure SE and the drain structure DE is preferably made of indium oxide (InO). In some embodiments of the present invention, optionally, the second atomic layer deposition cycle DE2 may be additionally performed one or more times before forming the first stacked channel layer CL1, thereby forming a third stacked channel layer (not shown) that has the same material as the second stacked channel layer CL2 and is interposed between the first stacked channel layer CL1 and the source structure SE, the drain structure DE, and the substrate 10. The thicknesses (numbers of the component layers) of the optional third stacked channel layer and the second stacked channel layer CL2 may be the same or different.

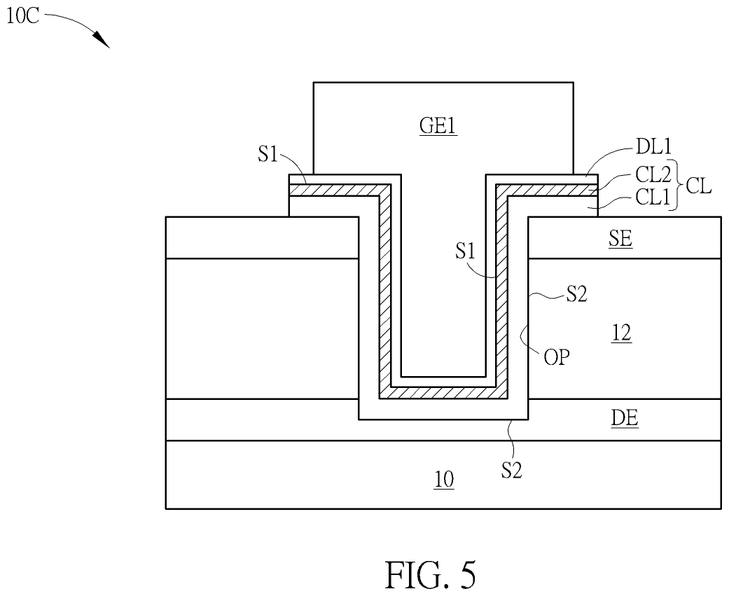

Please refer to FIG. 5, which is a schematic drawing illustrating a cross-sectional view of a semiconductor device 10C according to a third embodiment of the present invention. The semiconductor device 10C includes a substrate 10, a channel layer CL, a gate dielectric layer DL1, a gate structure GE1, and a source structure SE and a drain structure DE. The difference between the semiconductor device 10C shown in FIG. 5 and the semiconductor device 10A shown previously in FIG. 1 is that the semiconductor device 10C is a vertical channel transistor that has the source structure SE and the drain structure DE separated by an interlayer dielectric layer 12 and stacked one on the other on the substrate 10. The channel layer CL, the gate dielectric layer DL1, and the gate structure GE1 of the semiconductor device 10C are disposed along the sidewall of an opening OP that extends through the source structure SE, the interlayer dielectric layer 12, and part of the drain structure DE. The semiconductor device 10C may be formed by the following manufacturing steps. First, the substrate 10 is provided. Next, manufacturing processes such as deposition and patterning process are performed to sequentially form the drain structure DE, the interlayer dielectric layer 12, and the source structure SE on the substrate 10. The drain structure DE and the source structure SE are made of aluminum (Al), titanium (Ti), tantalum (Ta), tungsten (W), niobium (Nb), molybdenum (Mo), copper (Cu), titanium nitride (TiN), titanium carbide (TiC), tantalum nitride (TaN), titanium tungsten (Ti/W), titanium and titanium nitride (Ti/TiN), polysilicon, doped silicon, silicide, other suitable metal or non-metal conductive materials, or a combination thereof, but is not limited thereto. Following, an etching process is performed to form the opening OP through the source structure SE, the interlayer dielectric layer 12, and part of the drain structure DE. After that, M times of the first atomic layer deposition cycles DE1 (shown in FIG. 2) and N times of the second atomic layer deposition cycles DE2 (shown in FIG. 3) are performed to form the first stacked channel layer CL1 and the second stacked channel layer CL2 (collectively form the channel layer CL) conformally along the bottom surface and sidewalls of the opening OP. The materials and composition concentrations of the first stacked channel layer CL1 and the second stacked channel layer CL2 may be referred to the description as set forth in the first embodiment, and will not be repeated herein. Following, the gate dielectric layer DL1 is formed on the channel layer CL and a gate material layer (such as a conductive layer, not shown) is formed on the gate dielectric layer DL1 and completely fills the opening OP. Patterning processes are then performed to remove unnecessary portions of the gate material layer (not shown), the gate dielectric layer DL1, and the channel layer CL, thereby forming the patterned gate dielectric layer DL1, the gate structure GE1, and the channel layer CL as shown in FIG. 5. The portion of the channel layer CL on sidewalls of the opening OP is the vertical channel between the source structure SE and the drain structure DE. The conductivity of the channel layer CL is controlled by the gate structure GE1 in the opening OP.

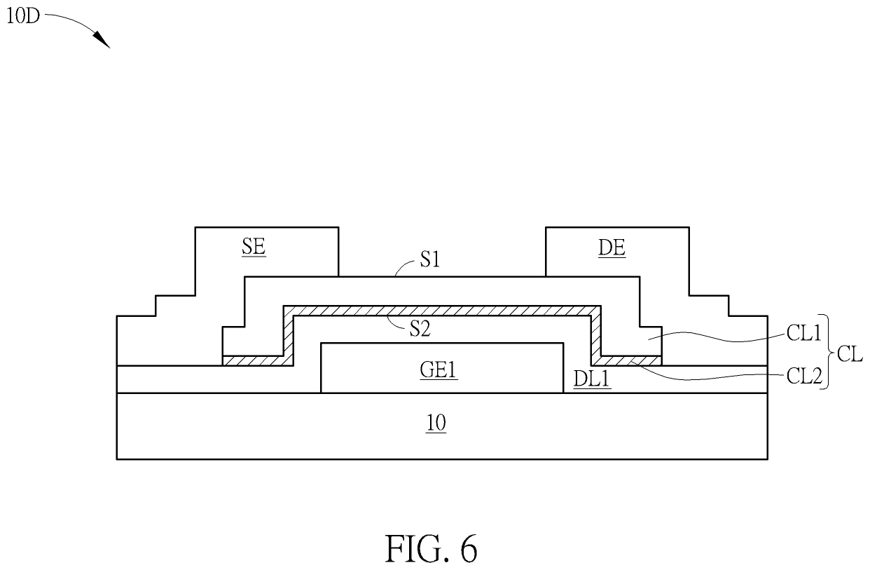

Please refer to FIG. 6, which is a schematic drawing illustrating a cross-sectional view of a semiconductor device 10D according to a fourth embodiment of the present invention. The semiconductor device 10D includes a substrate 10, a channel layer CL, a gate dielectric layer DL1, a gate structure GE1, and a source structure SE and a drain structure DE. The difference between the semiconductor device 10D shown in FIG. 6 and the semiconductor device 10A shown previously in FIG. 1 is that the semiconductor device 10D is a bottom gate transistor that has the gate structure GE1 disposed between the substrate 10 and the channel layer CL. The gate structure GE1 is on the second surface S2 of the channel layer CL opposite to the first surface S1 and the source structure SE and the drain structure DE. The semiconductor device 10D may be formed by the following manufacturing steps. First, the substrate 10 is provided. Next, a gate material layer (not shown) is formed on the substrate 10 and be patterned to form the gate structure GE1. Following, a deposition process is performed to form the gate dielectric layer DL1 on the substrate 10 and the gate structure GE1. Subsequently, N time of the second atomic layer deposition cycle DE2 (shown in FIG. 3) and M times of the first atomic layer deposition cycle DE1 (shown in FIG. 2) are performed to successively form the second stacked channel layer CL2 and the first stacked channel layer CL1 (collectively form the channel layer CL) on the substrate 10 and the gate structure GE1. The materials and composition concentrations of the first stacked channel layer CL1 and the second stacked channel layer CL2 may be referred to the description as set forth in the first embodiment, and will not be repeated herein. After patterning the channel layer CL, a conductive layer (not shown) is formed on the channel layer CL and then be patterned to form the source structure SE and the drain structure DE as shown in FIG. 6.

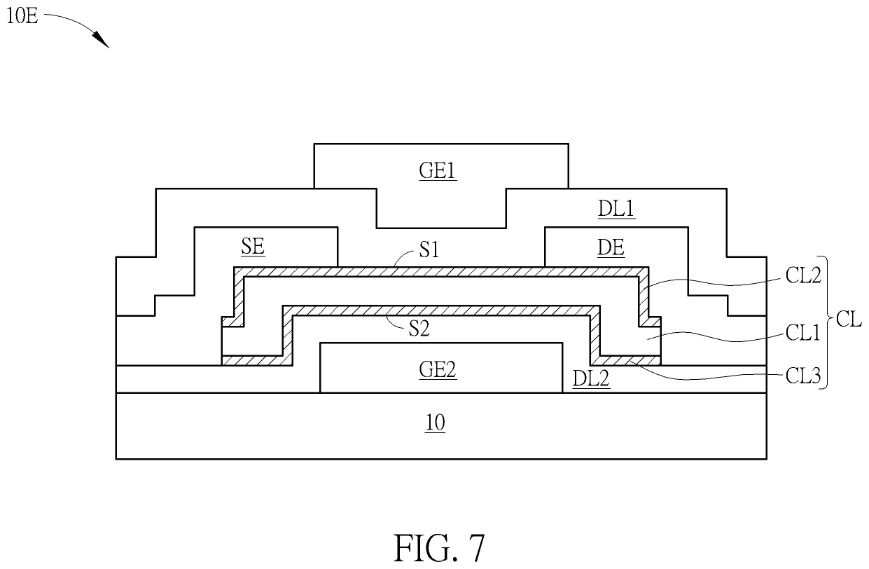

Please refer to FIG. 7, which is a schematic drawing illustrating a cross-sectional view of a semiconductor device 10E according to a fourth embodiment of the present invention. The difference between the semiconductor device 10E shown in FIG. 7 and the semiconductor device 10A shown previously in FIG. 1 is that the semiconductor device 10E is a dual-gate transistor. More particularly, the semiconductor device 10E includes a substrate 10, a channel layer CL disposed on the substrate 10, a source structure SE and a drain structure DE disposed on a first surface S1 of the channel layer CL opposite to the substrate 10, a gate structure GE1 (top gate structure) disposed on the first surface S1 of the channel layer CL, a gate dielectric layer DL1 (top gate dielectric layer) disposed between the channel layer CL and the gate structure GE1, another gate structure GE2 (bottom gate structure) disposed on a second surface S2 of the channel layer CL opposite to the gate structure GE1, and a gate dielectric layer DL2 (bottom gate dielectric layer) disposed between the channel layer CL and the gate structure GE2. As shown in FIG. 7, the channel layer CL of the semiconductor device 10E may be composed of a first stacked channel layer CL1, a second stacked channel layer CL2, and a third stacked channel layer CL3. The semiconductor device 10E may be formed by the following manufacturing steps. First, the substrate 10 is provided. Next, a gate material layer (not shown) is formed on the substrate 10 and then a patterning process is performed to pattern the gate material layer to form the gate structure GE2. Following, a deposition process is performed to form the gate dielectric layer DL2 on the substrate 10 and the gate structure GE2. Subsequently, the second atomic layer deposition cycle DE2 (shown in FIG. 3) is performed P times to form the third stacked channel layer CL3 on the gate dielectric layer DL2, wherein P is a positive integer equal to or larger than 1. After that, the first atomic layer deposition cycle DE1 (shown in FIG. 2) is performed M times to form the first stacked channel layer CL1 on the third stacked channel layer CL3, and then the second atomic layer deposition cycle DE2 (shown in FIG. 3) is performed N times to form the second stacked channel layer CL2 on the first stacked channel layer CL1. The third stacked channel layer CL3, the first stacked channel layer CL1, and the second stacked channel layer CL2 collectively form the channel layer CL. The materials and composition concentrations of the first stacked channel layer CL1 and the second stacked channel layer CL2 may be referred to the description as set forth in the first embodiment. The material and composition concentrations of the third stacked channel layer CL3 may be substantially the same as that of the second stacked channel layer CL2. However, the thicknesses of the third stacked channel layer CL3 and the second stacked channel layer CL2, respectively controlled by the number of times P and N, may be the same or different. After patterning the channel layer CL, manufacturing processes such as deposition, etching, and patterning processes are performed to form the source structure SE and the drain structure DE on the patterned channel layer CL at two sides of the gate structure GE. The gate dielectric layer DL is then formed on the channel layer CL, the source structure SE and the drain structure DE, and then the gate structure GE1 is formed on the gate dielectric layer DL. The channel layer CL of the semiconductor device 10E may be a three-part heterogeneous channel layer that the upper part (close to the gate structure GE1 and the lower part (close to the gate structure GE2) of the channel layer CL have higher In concentration and crystalline level, such that a stable threshold voltage and an increased carrier mobility may be achieved.

In conclusion, one feature of the present invention is that the oxide semiconductor channel layer of the semiconductor device is formed by a two-stage atomic layer deposition cycle, such that along the thickness direction the oxide semiconductor channel layer may be divided into two distinguishable portions that have different composition concentrations, wherein the portion farther from the gate structure is composed of alternately and repeatedly stacked layers of different oxide semiconductor materials, and the portion closer to the gate structure is essentially composed of layers of a oxide semiconductor material that is the main electron pathway former for the channel layer. In this way, a stable threshold voltage and an increased carrier mobility of the semiconductor device may be concurrently achieved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for forming a semiconductor device, comprising:
providing a substrate;
performing a first atomic layer deposition cycle M times to form a first stacked channel layer on the substrate;
performing a second atomic layer deposition cycle N times to form a second stacked channel layer on the first stacked channel layer, wherein M and N are positive integers, and a concentration of a metal composition of the second stacked channel layer is greater than a concentration of the metal composition of the first stacked channel layer;
forming a gate dielectric layer on the second stacked channel layer; and
forming a gate structure on the gate dielectric layer.

2. The method for forming a semiconductor device according to claim 1, wherein a processing temperature of the second atomic layer deposition cycles is higher than a processing temperature of the first atomic layer deposition cycles.

3. The method for forming a semiconductor device according to claim 1, wherein the metal composition comprises indium (In), the first stacked channel layer comprises indium oxide (InO), gallium oxide(GaO), and zinc oxide (ZnO), the second stacked channel layer comprises indium oxide (InO).

4. The method for forming a semiconductor device according to claim 1, wherein the first atomic layer deposition cycle comprises contacting the substrate alternately with an indium precursor, a gallium precursor, a zinc precursor, and an oxygen reactant, the second atomic layer deposition cycle comprises contacting the substrate alternately with the indium precursor and the oxygen reactant.

5. The method for forming a semiconductor device according to claim 4, wherein the indium precursor comprises [3-(dimethylamino) propyl] dimethyl indium (DADI), the gallium precursor comprises tri-methylgallium (TMGa), the zinc precursor comprises diethyl zinc, the oxygen reactant comprises oxygen.

6. The method for forming a semiconductor device according to claim 4, wherein each of the first atomic layer deposition cycle comprises sequentially performing the following:
performing a first sub-cycle m1 times, wherein the first sub-cycle comprises contacting the substrate with the indium precursor and then with the oxygen reactant;
performing a second sub-cycle m2 times, wherein the second sub-cycle comprises contacting the substrate with the gallium precursor and then with the oxygen reactant; and
performing a third sub-cycle m3 times, wherein the third sub-cycle comprising contacting the substrate with the zinc precursor and then with the oxygen reactant, wherein m1, m2 and m3 are positive integers.

7. The method for forming a semiconductor device according to claim 1, wherein a material of component layers of the second stacked channel layer and a material of a bottom-most component layer of the first stacked channel layer are the same.

8. The method for forming a semiconductor device according to claim 1, further comprising:
forming a source structure and a drain structure on the substrate; and
forming the first stacked channel layer on the substrate and directly covering the source structure and the drain structure.

9. A method for forming a semiconductor device, comprising:
providing a substrate;
forming a bottom electrode on the substrate;
forming a bottom gate dielectric layer on the substrate and covering the bottom electrode;
performing a first atomic layer deposition cycle N times to form a first stacked channel layer on the bottom gate dielectric layer; and
performing a second atomic layer deposition cycle M times to form a second stacked channel layer on the first stacked channel layer, wherein M and N are positive integers, and a concentration of a metal composition of the first stacked channel layer is greater than a concentration of the metal composition of the second stacked channel layer.

10. The method for forming a semiconductor device according to claim 9, wherein a processing temperature of the first atomic layer deposition cycles is higher than a processing temperature of the second atomic layer deposition cycles.

11. The method for forming a semiconductor device according to claim 9, wherein the metal composition comprises indium (In), the first stacked channel layer comprises indium oxide (InO), the second stacked channel layer comprises indium oxide (InO), gallium oxide(GaO), and zinc oxide (ZnO).

12. The method for forming a semiconductor device according to claim 9, wherein the first atomic layer deposition cycle comprises contacting the substrate alternately contacted with an indium precursor and an oxygen reactant, the second atomic layer deposition cycle comprises contacting the substrate alternately with the indium precursor, a gallium precursor, a zinc precursor, and the oxygen reactant.

13. The method for forming a semiconductor device according to claim 12, wherein the indium precursor comprises [3-(dimethylamino) propyl] dimethyl indium (DADI), the gallium precursor comprises tri-methylgallium (TMGa), the zinc precursor comprises diethyl zinc, the oxygen reactant comprises oxygen.

14. The method for forming a semiconductor device according to claim 12, wherein the each of the second atomic layer deposition cycle comprises sequentially performing the following:
performing a first sub-cycle m1 times, wherein the first sub-cycle comprises contacting the substrate with the indium precursor and then with the oxygen reactant;
performing a second sub-cycle m2 times, wherein the second sub-cycle comprises contacting the substrate with the gallium precursor and then with the oxygen reactant; and
performing a third sub-cycle m3 times, wherein the third sub-cycle comprising contacting the substrate with the zinc precursor and then with the oxygen reactant, wherein m1, m2 and m3 are positive integers.

15. The method for forming a semiconductor device according to claim 9, wherein a material of a bottom-most component layer of the second stacked channel layer and a material of component layers of the first stacked channel layer comprise the same.

16. The method for forming a semiconductor device according to claim 9, further comprising:
performing the first atomic layer deposition cycle P times to form a third stacked channel layer on the second stacked channel layer;
forming a source structure and a drain structure on the third stacked channel layer and at two sides of the bottom gate structure.

17. A semiconductor device, comprising:
a first stacked channel layer comprising a first surface and a second surface;
a first gate structure disposed on the first surface of the first stacked channel layer;
a first gate dielectric layer disposed between the first gate structure and the first stacked channel layer; and
a second stacked channel layer disposed between the first gate dielectric layer and the first stacked channel layer, wherein a concentration of a metal composition of the second stacked channel layer is greater than a concentration of the metal composition of the first stacked channel layer.

18. The semiconductor device according to claim 17, wherein the metal composition comprises indium (In), the first stacked channel layer comprises indium oxide (InO), gallium oxide(GaO), and zinc oxide (ZnO), the second stacked channel layer comprises indium oxide (InO).

19. The semiconductor device according to claim 17, a material of a component layer exposed from the second surface of the first stacked channel layer and a material of component layers of the second stacked channel layer are the same.

20. The semiconductor device according to claim 17, further comprising:
a second gate structure disposed on the second surface of the first stacked channel layer;
a second gate dielectric layer disposed between the second gate structure and the first stacked channel layer; and
a third stacked channel layer disposed between the second gate dielectric layer and the first stacked channel layer, wherein a concentration of the metal composition of the third stacked channel layer is the same as the concentration of the metal composition of the second stacked channel layer.
